(19) United States
(12) Patent Application Publication
(10) Pub. No.: US 2010/0295593 A1
(43) Pub. Date: Nov. 25, 2010

(54) DELAY CIRCUIT

(75) Inventor: Masahiro YOSHIDA, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/772,667

(22) Filed: May 3, 2010

(30) Foreign Application Priority Data
May 22, 2009 (JP) 2009-124158

(51) Int. Cl. H03H 11/26

(52) U.S. Cl. 327/285

(57) ABSTRACT

A delay circuit (100) includes capacitor elements constituted of nMOS transistors (141, 142) between an input inverter circuit (110) and an output inverter circuit (120). The input inverter circuit (110) includes a pMOS transistor (PM1) and an nMOS transistor (NM1) that are directly connected between a power source potential (VDD) and a ground potential (VSS) through a resistor (R1). Between a signal line (130) and the gate of the nMOS transistor (141), and between the signal line (130) and the gate of the nMOS transistor (142), pMOS transistors (151, 152) are provided, respectively. In this structure, in the case where an input signal is changed from L to H, the PVT sensitivity of a delay circuit is automatically alleviated. As a result, the PVT sensitivity is automatically alleviated.

### INCORPORATION BY REFERENCE

This application is based upon and claims the benefit of priority from Japanese patent application No. 2009-124158, filed on May 22, 2009, the disclosure of which is incorporated herein in its entirety by reference.

### BACKGROUND

1. Field of the Invention

The present invention relates to a delay circuit. More specifically, the present invention relates to a delay circuit that automatically alleviates and adjusts the sensitivity of PVT (process, voltage, and temperature).

2. Description of Related Art

A delay circuit is used for performing a phase adjustment between signals.

FIG. 7 is a diagram showing a delay circuit in related art (Japanese Unexamined Patent Application Publication No. 09-172356 (FIGS. 1 and 5)).

In FIG. 7, a plurality of capacitors 3, 3a, and 3b are disposed between a first inverting buffer 1 and a second inverting buffer 1a. In FIG. 7, three capacitors 3, 3a, and 3b are disposed. Further, by opening and closing switches 2, 2a, and 2b that are directly connected to the three capacitors 3, 3a, and 3b, respectively, a capacitance connected between the inverting buffers 1 and 1a can be varied.

The operation of the delay circuit shown in FIG. 7 will be described.

The assumption is made that a rectangular wave is applied to an input terminal.

In the case where the rectangular wave is a level of “1”, the first inverting buffer 1 causes the capacitors (3, 3a, and 3b) to perform electrical discharge. As a result, terminal voltages of the capacitors (3, 3a, and 3b) are reduced. When the terminal voltages of the capacitors (3, 3a, and 3b) reach a threshold value of the second inverting buffer 1a, the output of the second inverting buffer 1a becomes “1”.

On the other hand, in the case where the rectangular wave is a level of “0”, the first inverting buffer 1 causes the capacitors (3, 3a, and 3b) to be recharged. As a result, the terminal voltages of the capacitors (3, 3a, and 3b) are increased. When the terminal voltages of the capacitors reach the threshold value of the second inverting buffer 1a, the output of the second inverting buffer 1a becomes “0”.

In this way, a time period from a rise time of an input signal to a time until the terminal voltages of the capacitors (3, 3a, and 3b) reach the threshold value of the second inverting buffer 1a corresponds to a delay time. Further, because the capacitances of the capacitors (3, 3a, and 3b) can be varied by selectively opening and closing the switches 2, 2a, and 2b, an arbitrary delay time can be set.

Further, the structure shown in FIG. 8 is the same as that of FIG. 7 in principle. In the structure of FIG. 8, switches are formed of transmission gates 6, 6a, and 6b, and capacitors are formed of field effect transistors 4b, 4c, 4d, 5b, 5c, and 5d.

In recent years, the operation power supply voltage of a semiconductor device is being reduced.

In the semiconductor device, a change in operation speed is caused due to PVT (Process, Voltage, and Temperature) characteristics. For example, a negative temperature characteristic of signal delay characteristics becomes obvious. In view of this, it is necessary to alleviate the PVT sensitivity by performing a timing adjustment with a delay circuit. For example, in the structures shown in FIGS. 7 and 8, a delay-adjustment logic circuit is provided to adjust the switching, thereby performing the timing adjustment to alleviate the PVT sensitivity.

### SUMMARY

It has now been discovered that the delay-adjustment logic circuit itself has the PVT sensitivity in the case where the delay-adjustment logic circuit is provided to perform the switching control. Further, the PVT sensitivity becomes larger by such a degree that the circuit is additionally provided, which causes a problem of going against the alleviation of the PVT sensitivity.

According to an aspect of the present invention, there is provided a delay circuit including an input inverter circuit, an output inverter circuit, a capacitor element, and a switch transistor. The input inverter circuit includes a drive transistor connected to a first power source, an input signal being inputted to the input inverter circuit. The output inverter circuit has an input node to which a delay control node that is an output terminal of the input inverter circuit is connected through a signal line. The capacitor element is connected between the signal line and a second power source. The switch transistor is provided between the signal line and the capacitor element. The drive transistor and the switch transistor are semiconductor transistors that have the same conductivity type.

With this structure, the operation timing lag of the drive transistor due to the PVT characteristics is automatically compensated by the operation timing lag of the switch transistor. As a result, the PVT sensitivity of the entire delay circuit is automatically alleviated.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a diagram showing a delay circuit according to a first embodiment of the present invention;

FIG. 2 is a timing chart for explaining an operation at a time when an input varies from L to H;

FIG. 3 is a timing chart for explaining the automatic alleviation of PVT sensitivity in the case where a threshold voltage Vtp becomes large;

FIG. 4 is a timing chart for explaining the automatic alleviation of the PVT sensitivity in the case where the threshold voltage Vtp becomes small;

FIG. 5 is a diagram showing Modified Example 1;

FIG. 6 is a diagram showing Modified Example 2;

FIG. 7 is a diagram showing a delay circuit in related art; and

FIG. 8 is a diagram showing a delay circuit in related art.

### DETAILED DESCRIPTION OF THE EXEMPLARY EMBODIMENTS

Hereinafter, embodiments of the present invention will be shown and described with reference to reference numerals and symbols assigned to components in the figures.

### First Embodiment

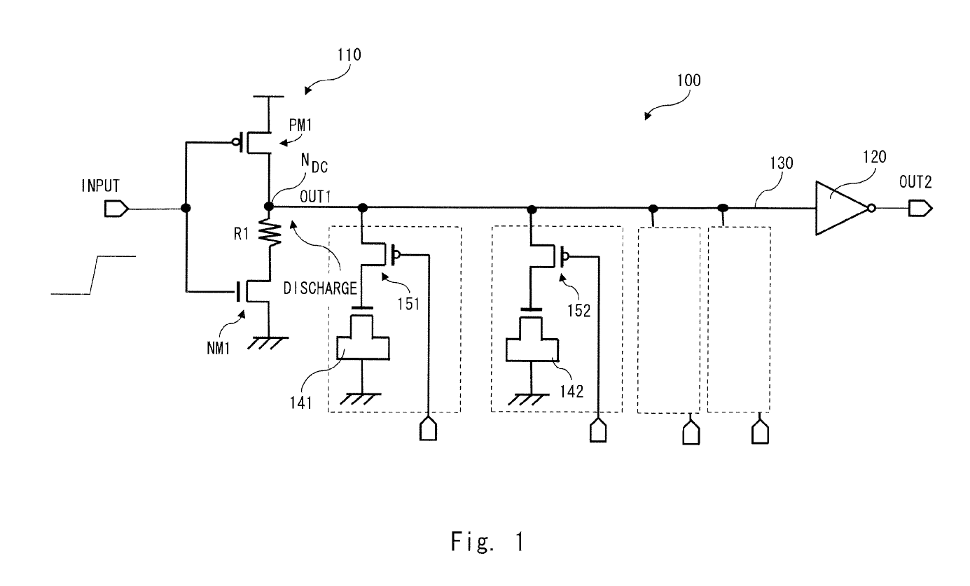

FIG. 1 is a delay circuit according to a first embodiment of the present invention.

In the first embodiment, a delay circuit automatically alleviates PVT sensitivity when an input signal varies from L (low) to H (high).

A delay circuit 100 includes a capacitor element between an input inverter circuit 110 and an output inverter circuit 120.

The output of the input inverter circuit 110 and the input of the output inverter circuit 120 are connected to each other through a signal line 130.

The input inverter circuit 110 includes a pMOS transistor (first transistor) PM1 and an nMOS transistor (sixth transistor) NM1 that are directly connected between a power source potential VDD and a ground potential VSS through a resistor R1.

Here, the output node of the input inverter circuit 110 which is a contact point between the pMOS transistor PM1 and the resistor R1 is referred to as a delay control node (contact point) N_{DC}, and the output thereof is referred to as an output OUT1.

Further, the output of the output inverter circuit 120 is referred to as an output OUT2.

The capacitor element is constituted of nMOS transistors 141 and 142.

The drain and the source of the nMOS transistors 141 and 142 are connected, and the contact point is connected to a ground (low potential side).

Here, the nMOS transistor (third transistor) 141 forms a first capacitor element, and the nMOS transistor (fifth transistor) 142 forms a second capacitor element.

Between the signal line 130 and the gates of the nMOS transistors 141 and 142, a pMOS transistor (second transistor) 151 and a pMOS transistor (fourth transistor) 152 are provided, respectively.

The sources of the pMOS transistors 151 and 152 are connected to the signal line 130, and the drains thereof are connected to the gates of the nMOS transistors 141 and 142 as the capacitor elements, respectively.

Further, the gates of the pMOS transistors 151 and 152 are fixed to an L level.

It should be noted that sets of the pMOS transistors 151 and 152 and the nMOS transistors 141 and 142 are provided to the signal line 130 by a predetermined number.

Here, the power source VDD (power source on a high voltage side) serves as a first power source, and a ground power source (power source on a low voltage side) serves as a second power source. Further, the pMOS transistor PM1 forms a drive transistor, and the pMOS transistors 151 and 152 each form a switch transistor.

In addition, in the structure of the inverter circuit 110, the load resistor R1 and the nMOS transistor NM1 are not essential components, and can be selectively eliminated.

A description will be given on the case where a signal varied from I to II is input to the input terminal in the above structure.

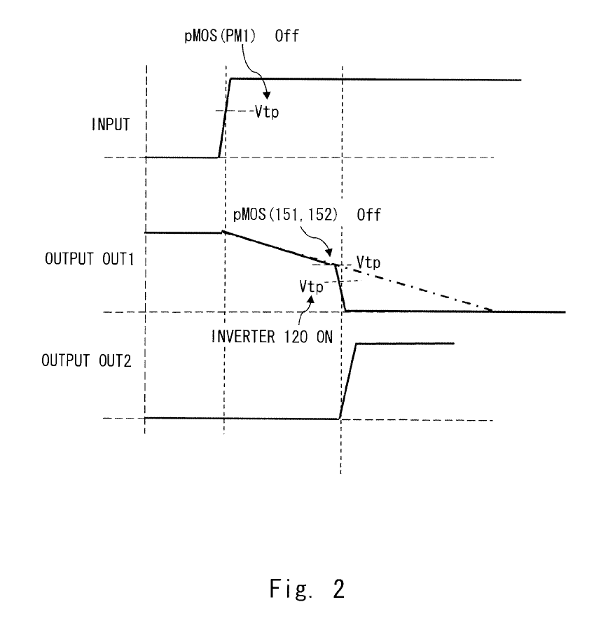

FIG. 2 is a timing chart for explaining an operation at a time when the input is varied from L to H.

The pMOS transistor PM1 is in an on state at the start, because the input is the L level.

The delay control node N_{DC} of the input inverter circuit 110 is connected to the power source VDD, so the output OUT1 is a high level.

Further, the pMOS transistors 151 and 152 as the switches are in the on state, because the L-level voltage is applied to the gates thereof. Therefore, charges are supplied to the nMOS transistors 141 and 142 as the capacitor elements.

When the input signal is varied from the L level to the H level, and a potential difference between the source and the drain of the pMOS transistor PM1 becomes smaller than a threshold value Vtp of the pMOS transistor PM1, the pMOS transistor PM1 is turned off.

At the same time, the nMOS transistor NM1 is turned on, and the delay control node N_{DC} is connected to a ground power source. As a result, the potential of the delay control node N_{DC} is lowered, but the charges are released from the nMOS transistors 141 and 142 serving as the capacitor elements. Therefore, the potential of the delay control node N_{DC} is gradually lowered.

When the potential of the delay control node N_{DC} is lowered, and the potential difference between the source and the gate of the pMOS transistors 151 and 152 serving as the switches becomes less than the threshold value Vtp, the pMOS transistors 151 and 152 are turned off. As a result, the delay control node N_{DC} is separated from the nMOS transistors 141 and 142 serving as the capacitor elements.

In this state, the charges from the capacitor elements (141 and 142) are not discharged to the delay control node N_{DC}, and therefore the potential of the delay control node N_{DC} begins to be rapidly lowered.

When the potential of the delay control node N_{DC} is lowered up to the threshold value Vtp of the pMOS transistor of the output inverter 120, the output inverter circuit 120 is turned on, and an output level OUT2 becomes an H level.

Next, as an effect obtained from this embodiment, the automatic alleviation of the PVT sensitivity will be described.

For example, an assumption is made that the threshold voltage Vtp of the pMOS transistors (PM1, 151, and 152) is increased due to a low environment temperature or the variation in a manufacturing process.

The threshold value in this case is represented by Vtp (H).

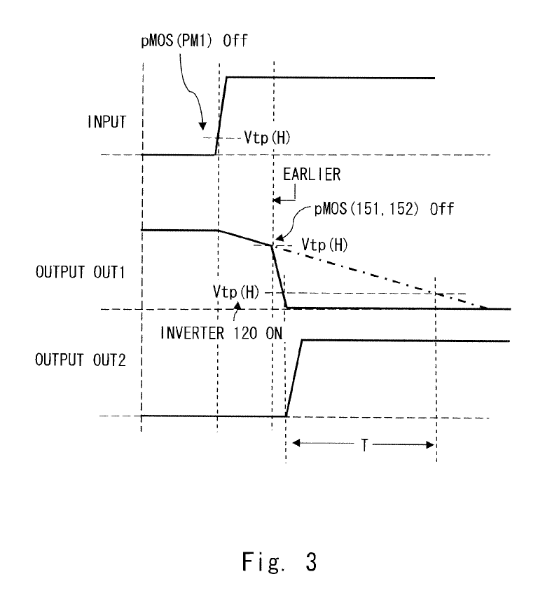

The timing chart in this case is shown in FIG. 3.

When the input is varied from the L level to the H level, and the voltage between the source and the gate of the pMOS transistor PM1 becomes smaller than Vtp (H), the pMOS transistor PM1 of the input inverter circuit 110 is turned off.

The potential of the delay control node N_{DC} is lowered while receiving the electrical discharge from the nMOS transistors 141 and 142. Subsequently, when the potential of the delay control node N_{DC} is lowered, and the voltage between the source and the gate of the pMOS transistor 151 and 152 becomes smaller than the Vtp (H), the pMOS transistors 151 and 152 are turned off.

At this time, the threshold voltage of the pMOS transistors 151 and 152 is Vtp (H), and thus the PMOS transistors 151 and 152 are turned off at an earlier timing.

When the pMOS transistors 151 and 152 are turned off, the delay control node N_{DC} is separated from the capacitor elements (141 and 142). Therefore, the potential of the delay control node N_{DC} becomes rapidly lowered. Subsequently, when the potential of the delay control node N_{DC} is lowered up to the threshold value Vtp (H) of the pMOS transistor of the output inverter 120, the output inverter circuit 120 is turned on, and the output level OUT2 becomes the H level.

As described above, due to the environment temperature or the manufacturing process, the threshold value Vtp of the pMOS transistor may become larger. In this case, in the changing of the input signal from L to H, the pMOS transistors 151 and 152 serving as the switches are turned off at an earlier timing.

Because the pMOS transistors 151 and 152 are turned off at an earlier timing, the delay control node N_{DC} is separated from the capacitor elements (141 and 142) at an earlier timing.

As a result, the lag amount of the delay timing of the output OUT2 is reduced, with the result that the PVT sensitivity is automatically alleviated.

As shown in FIG. 3, the rising of the output OUT2 is caused at the earlier timing by T as compared to a case where the switches of the pMOS transistors 151 and 152 are not provided.

In this way, the PVT sensitivity can be alleviated and the delay is reduced under the worst condition of reaching the threshold value Vtp (H).

Next, for example, an assumption is made that the threshold voltage Vtp of the pMOS transistors (PM1, 151, and 152) becomes smaller due to a high environment temperature or the variation of the manufacturing process.

The threshold value in this case is represented by Vtp (L).

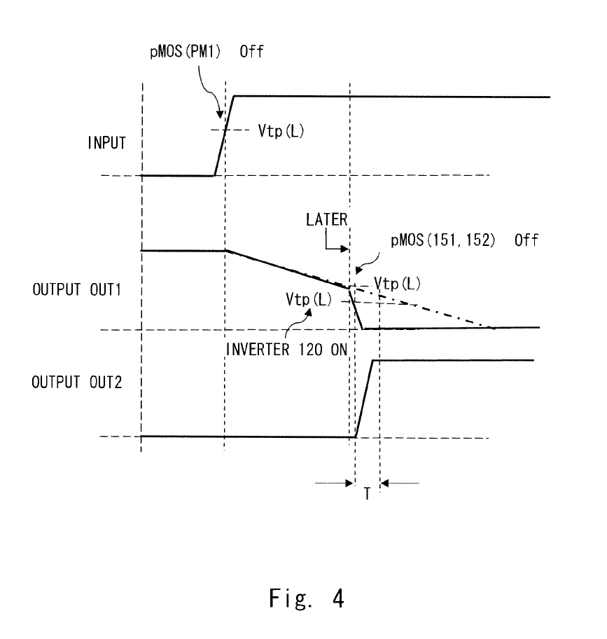

The timing chart in this case is shown in FIG. 4.

When the input is varied from the L level to the H level, and the potential difference between the source and the gate of the pMOS transistor PM1 becomes smaller than Vtp (L), the pMOS transistor PM1 of the input inverter circuit 110 is turned off.

The potential of the delay control node N_{D} (is lowered while receiving the electrical discharge from the nMOS transistors 141 and 142. Subsequently, when the potential of the delay control node N_{DC} is lowered and the voltage between the source and the gate of the pMOS transistors 151 and 152 becomes smaller than Vtp (L), the pMOS transistors 151 and 152 are turned off.

At this time, because the threshold voltage of the pMOS transistors 151 and 152 are lowered to be Vtp (L), the pMOS transistors 151 and 152 are turned off at a later timing.

When the pMOS transistors 151 and 152 are turned off, the delay control node N_{DC} is separated from the capacitor elements (141 and 142). Therefore, the potential of the delay control node N_{DC} is rapidly lowered.

When the potential of the delay control node N_{DS} is lowered up to the threshold value Vtp (L) of the pMOS transistor of the output inverter circuit 120, the output inverter circuit 120 is turned on, and the output level OUT2 is changed to be the H level.

As described above, due to the environment temperature or the manufacturing process, the threshold value Vtp of the pMOS transistor may be lowered. In this case, in the changing of the input signal from L to H, the pMOS transistors 151 and 152 are turned off at a later timing. Because the pMOS transistors 151 and 152 are turned off at a later timing, the delay control node N_{DC} is separated from the capacitor elements (141 and 142) at a later timing.

When the threshold value Vtp of the pMOS transistor becomes smaller, the inverter circuit 120 is turned on at an earlier timing, but by this time period, the timing of turning the pMOS transistors 151 and 152 off is delayed, thereby reducing the lag amount of the delay timing of the output OUT2. As a result, the PVT sensitivity is automatically alleviated.

As described above, according to the delay circuit 100 of the first embodiment, in the changing of the input signal from L to H, the lag of the delay timing due to the PVT sensitivity is automatically alleviated.

### Modified Example 1

In the first embodiment, the gates of the pMOS transistors 151 and 152 are fixed at the L level.

In contrast, a predetermined delay adjustment logic circuit 200 may be additionally provided, and a control signal of the delay adjustment logic circuit 200 may be applied to the gates of the pMOS transistors 151 and 152.

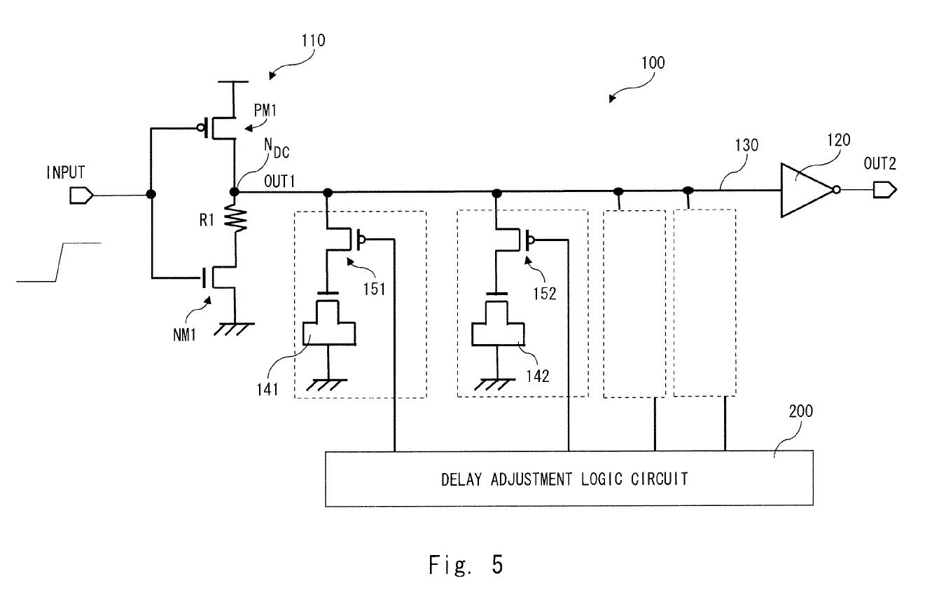

Modified example 1 of this case is shown in FIG. 5.

In this structure, the plurality of pMOS transistors 151 and 152 are switched to be turned on or off, respectively, thereby changing the number of the capacitor elements (141 and 142) connected to the delay control node N_{DC}. As a result, the amount of delay caused by the delay circuit 100 can be changed. Also in this case, a logic circuit is not added to a delay path, so the automatic alleviation of the PVT sensitivity described in the above embodiment effectively functions.

As a result, while controlling the delay amount by using the delay adjustment logic circuit 200, the PVT sensitivity can be automatically alleviated, and the optimal delay adjustment can be performed.

### Modified Example 2

In the above embodiment, the description is given on the delay circuit that automatically alleviates the PVT sensitivity in the case where the input signal is varied from L to H.

In contrast, by replacing a circuit element with a complementary element, it is possible to obtain a delay circuit that automatically alleviates the PVT sensitivity in the case where the input signal is varied from H to L.

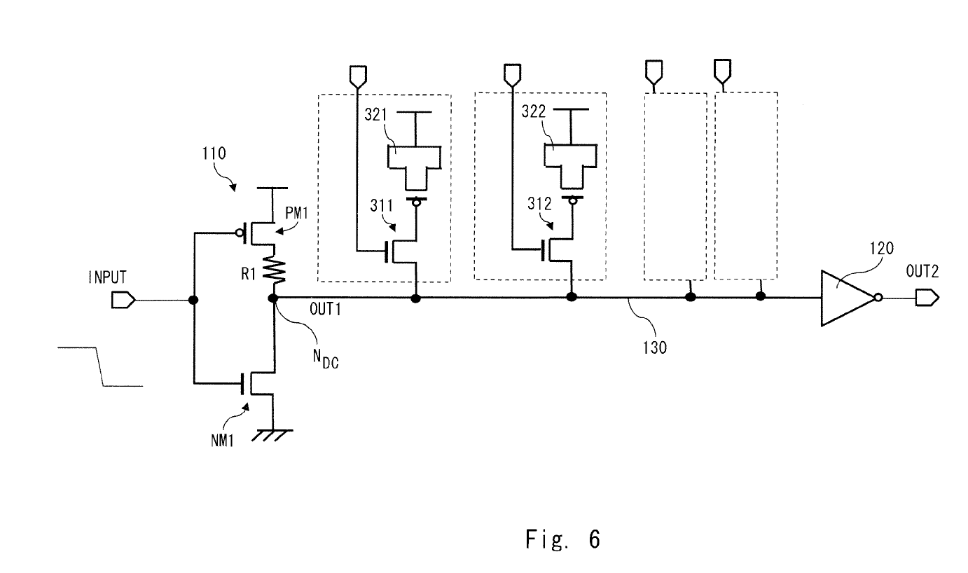

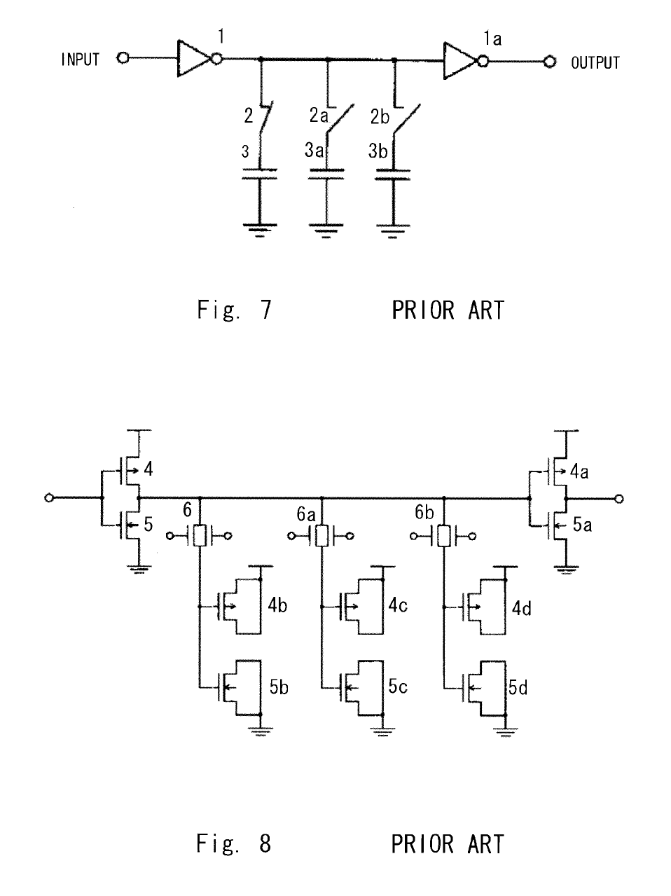

The structure of this case is shown in FIG. 6.

In FIG. 6, switches connected to a delay control node are nMOS transistors 311 and 312, and capacitor elements are pMOS transistors 321 and 322.

Here, a ground power source is a first power source, a power source VDD is a second power source, the nMOS transistor NM1 is a drive transistor, and the nMOS transistors 311 and 312 are switch transistors.

With this structure, in the case where the input signal is varied from H to L, that is, in the case where the delay control node N_{DC} is varied from L to H, the PVT sensitivity of the delay can be automatically alleviated.

It should be noted that the present invention is not limited to the above embodiments, and modifications, improvements, and the like within the range in which the object of the present invention can be attained are included in the present invention.

For example, the capacitor element may not necessarily be the semiconductor transistor but may be a capacitor, of course.

While the invention has been described in terms of several exemplary embodiments, those skilled in the art will recognize that the invention can be practiced with various modifications within the spirit and scope of the appended claims and the invention is not limited to the examples described above.

The exemplary embodiments mentioned above can be combined as desirable by one of ordinary skill in the art.

Further, the scope of the claims is not limited by the exemplary embodiments described above.

Furthermore, it is noted that, Applicant's intent is to encompass equivalents of all claim elements, even if amended later during prosecution.

What is claimed is:

1. A delay circuit comprising:
an input inverter circuit that includes a drive transistor connected to a first power source, an input signal being inputted to the input inverter circuit;
an output inverter circuit that has an input node to which a delay control node that is an output terminal of the input inverter circuit is connected through a signal line;
a capacitor element that is connected between the signal line and a second power source; and
a switch transistor that is provided between the signal line and the capacitor element,
wherein the drive transistor and the switch transistor are semiconductor transistors that have the same conductivity type.

2. The delay circuit according to claim 1, wherein
the first power source is a high-voltage side power source,
the second power source is a low-voltage side power source, and
the drive transistor and the switch transistor are P-type semiconductor transistors.

3. The delay circuit according to claim 1, wherein
the first power source is a low-voltage side power source;
the second power source is a high-voltage side power source; and
the drive transistor and the switch transistor are N-type semiconductor transistors.

4. The delay circuit according to claim 1, wherein
a plurality of sets of the capacitor element and the switch transistor is provided between the input inverter circuit and the output inverter circuit, and
the switch transistor is subjected to a selective on/off control in accordance with an amount of delay adjustment of the delay circuit.

5. The delay circuit according to claim 1, wherein the capacitor element is formed of a semiconductor transistor whose conductivity type is opposite to that of the switch transistor.

6. A delay circuit comprising:
a first transistor that has a first conductivity type and has a contact point set to a predetermined potential;
a second transistor that has the first conductivity type and is connected to the contact point; and
a first capacity element that is connected to the second transistor, the first capacitor element having a variable load state with respect to the contact point in accordance with a potential difference between a gate potential of the second transistor and the potential of the contact point.

7. The delay circuit according to claim 6, wherein the capacitor element is formed of a third transistor whose conductivity type is opposite to that of the first transistor.

8. The delay circuit according to claim 6, further comprising:
a fourth transistor that that has the same conductivity type as that of the second transistor and is connected to the contact point; and
a second capacitor element that is connected to the first transistor.

9. The delay circuit according to claim 8, wherein the second capacitor element is formed of a fifth transistor that has a conductivity type opposite to that of the first transistor.

10. The delay circuit according to claim 6, further comprising a sixth transistor that has a conductivity type opposite to the first conductivity type and is connected to the contact point,
wherein the first transistor and the sixth transistor constitute an inverter circuit.

11. The delay circuit according to claim 10, further comprising a resistor element between the contact point and the sixth transistor.

12. The delay circuit according to claim 8, wherein a gate potential of the second transistor and a gate potential of the fourth transistor are each set to a complementary potential.
